(19) United States
(12) Patent Application Publication
(10) Pub. No.: US 2007/0120126 A1
(43) Pub. Date: May 31, 2007

(54) Organic light emitting display device and method for manufacturing the same

(76) Inventors: Dong-Young Sung, Yongin-si (KR); Woong-Sik Choi, Yongin-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/605,745

(22) Filed: Nov. 29, 2006

(30) Foreign Application Priority Data
Nov. 29, 2005 (KR) 10-2005-0114785

(51) Int. Cl. H01L 29/08; H01L 29/04; H01L 33/00

(52) U.S. Cl. 257/59; 257/40; 257/103

(57) ABSTRACT

An organic light emitting display device and method for manufacturing the same is disclosed. The organic light emitting display device includes a driving circuit unit, a light emitting unit, and a common electric line. The driving circuit unit includes first and second thin film transistors arranged in a subpixel area on a substrate. The light emitting unit is formed on the driving circuit unit. The light emitting unit includes a first electrode electrically connected to a drain electrode of the second thin film transistor, a second electrode arranged on the first electrode, and a light emitting layer formed between the first and second electrodes. The common electric line is electrically connected to a source electrode of the second thin film transistor. The common electric line and the first electrode are formed on the same layer. The common electric line includes the same material as that comprised in the first electrode.

### CROSS-REFERENCE TO RELATED APPLICATION

This application claims priority to and the benefit of Korean Patent Application No. 10-2005-0114785 filed in the Korean Intellectual Property Office on Nov. 29, 2005, the entire content of which is incorporated herein by reference.

### BACKGROUND OF THE INVENTION

1. Field of the Invention

The present invention relates to an organic light emitting display device and method for manufacturing the same.

2. Description of the Related Technology

Recently, various kinds of flat panel display (FPD) devices have been developed. These devices can greatly reduce its weight and volume in comparison with a cathode ray tube (CRT). The FPD devices include a liquid display device (LCD), a field emission display (FED), a plasma display panel (PDP), an organic light emitting display (OLED) and so on.

Among the above FPD devices, the OLED is a self-emissive display device which electrically excites organic compounds and emits light. In the OLED, a plurality of organic light emitting units are driven by voltage or current and then image is displayed.

The organic light emitting units are referred to as organic light emitting diodes because they electrically perform as diodes. The organic light emitting diode includes an anode electrode for injecting holes, an organic thin film for emitting light, and a cathode electrode for injecting electrons. The organic thin film is multi-layered and includes an electron transport layer (ETL), a hole transport layer (HTL), an electron injection layer (EIL), and a hole injection layer (HIL).

The holes and electrons are injected into the organic thin film. Then, they are combined with each other and then exitons are generated. The exitons fall from an excitation state to a ground state and then light is emitted.

### SUMMARY OF CERTAIN INVENTIVE ASPECTS

One aspect of the present invention provides an organic light emitting display device including i) a driving circuit unit comprising first and second thin film transistors arranged in a subpixel area on a substrate, ii) a light emitting unit formed on the driving circuit unit, iii) a common electric line electrically connected to a source electrode of the second thin film transistor. The light emitting unit includes i) a first electrode electrically connected to a drain electrode of the second thin film transistor, ii) a second electrode arranged on the first electrode, and iii) a light emitting layer formed between the first and second electrodes. The common electric line and the first electrode may be formed on the same layer and are formed of the same material.

The first electrode may be an anode electrode. The anode electrode may include silver (Ag). The anode electrode may include i) a first layer comprising indium tin oxide, ii) a second layer comprising silver formed on the first layer, and iii) a third layer comprising indium tin oxide formed on the second layer.

In an embodiment, the second thin film transistor may include i) a second semiconductor layer including a source area, a drain area, and a channel area, ii) a second gate electrode formed on the second semiconductor layer, and iii) source and drain electrodes formed on the second gate electrode. A gate insulating layer may be formed between the second semiconductor layer and the second gate electrode, and an interlayer dielectric may be formed between the second gate electrode and the source and drain electrodes.

A first gate electrode of the first thin film transistor and a scan line electrically connected to the first gate electrode may be formed on the gate insulating layer. The source and drain electrodes of the first thin film transistor and a data line may be formed on the interlayer dielectric. The data line may be integrally formed with the source electrode of the first thin film transistor. A lower capacitor electrode may be formed on the gate insulating layer. The lower capacitor electrode may be integrally formed with the second gate electrode. An upper capacitor electrode may be formed on the interlayer dielectric.

A planarization layer may be formed on the upper capacitor electrode. The lower capacitor electrode may be electrically connected to the drain electrode of the first thin film transistor. The upper capacitor electrode may be electrically connected to a common electric line formed on the planarization layer.

A planarization layer may be formed on the upper capacitor electrode. An auxiliary common electric line may be formed on the interlayer dielectric. At least one of the source electrode of the second thin film transistor and the upper capacitor electrode may be electrically connected to a common electric line formed on the planarization layer. The auxiliary common electric line may be integrally formed with the upper capacitor electrode and the source electrode of the second thin film transistor.

The auxiliary common electric line may be electrically isolated from a subpixel which is adjacent to the subpixel area in a lengthwise direction of the common electric line. The auxiliary common electric line may be electrically connected to a subpixel which is adjacent to the subpixel area in a lengthwise direction of the common electric line.

Another aspect of the present invention provides an organic light emitting display device including i) a substrate, ii) a first semiconductor layer of first thin film transistor layer and a second semiconductor layer of a second thin film transistor layer in a subpixel area on the substrate, iii) a gate insulating layer formed on the first and second semiconductor layers, iv) a first gate electrode of the first thin film transistor, a second gate electrode of the second thin film transistor, and a scan line electrically connected to the first gate electrode formed on the gate insulating layer, v) an interlayer dielectric formed on the first and second gate electrodes, the scan line and the gate insulating layer, vi) respective source and drain electrodes of the first and second thin film transistors and a data line formed on the interlayer dielectric, wherein the data line is formed with the source electrode of the first thin film transistor, and arranged to cross the scan line, vii) a planarization layer formed on the respective source and drain electrodes of the first and second thin film transistors, the data line, and the interlayer dielectric, viii) a light emitting unit formed on the planarization layer, and ix) a common electric line electrically connected to the source electrode of the second thin film transistor. Each semiconductor layer includes a source area, a drain area; and a channel area. The light emitting unit formed on the planarization layer includes i) a first electrode electrically connected to the drain electrode of the second thin film transistor, ii) a light emitting layer formed on the first electrode, and iii) a second electrode formed on the light emitting layer. The common electric line and the first electrode of the light emitting unit are formed on the same layer and are formed of the same material.

The organic light emitting display device further includes i) a lower capacitor electrode, comprising the same material as the second gate electrode, and formed on the gate insulating layer, and ii) an upper capacitor electrode formed between the interlayer dielectric and the planarization layer, wherein the lower capacitor electrode is electrically connected to the drain electrode of the first thin film transistor, and the upper capacitor electrode is electrically connected to the common electric line.

The organic light emitting display device further includes i) an auxiliary common electric line, which is integrally formed on the interlayer dielectric with the upper capacitor electrode and the source electrode of the second thin film transistor. The auxiliary common electric line may be electrically isolated from a subpixel which is adjacent to the subpixel area in a lengthwise direction of the common electric line. The auxiliary common electric line may be electrically connected to a subpixel which is adjacent to the subpixel area in a lengthwise direction of the common electric.

The first electrode of the light emitting unit may be an anode electrode. The anode electrode may include silver. The anode electrode may include i) a first layer comprising indium tin oxide, ii) a second layer comprising silver formed on the first layer, and iii) a third layer comprising indium tin oxide formed on the second layer.

Another aspect of the present invention provides a method for manufacturing an organic light emitting display device. The method includes i) providing a substrate, ii) forming a first semiconductor layer of a first thin film transistor and a second semiconductor layer of a second thin film transistor in a subpixel area on the substrate, iii) forming a gate insulating layer on the first and second semiconductor layers, iv) forming on the gate insulating layer, a first gate electrode of the first thin film transistor, a scan line connected to the first gate electrode, a second gate electrode of the second thin film transistor, and a lower capacitor electrode connected to the second gate electrode, v) forming an interlayer dielectric on the first and second gate electrodes, the scan line and the lower capacitor electrode, vi) forming respective source and drain electrodes of the first and second thin film transistors, a data line integrally formed with the source electrode of the first thin film transistor, and an upper capacitor electrode, vii) forming a planarization layer on the interlayer dielectric, viii) forming a common electric line electrically connected to the source electrode of the second thin film transistor and the upper capacitor electrode, the common electric line comprising the same material as a first light emitting unit electrode electrically connected to the drain electrode of the second thin film transistor, and ix) sequentially stacking a light emitting layer and a second light emitting unit electrode on the first light emitting unit electrode.

The method for manufacturing an organic light emitting display device further includes forming an auxiliary common electric line integrally formed with the upper capacitor electrode and the source electrode of the second thin film transistor. The method for manufacturing an organic light emitting display device further includes electrically isolating the auxiliary common electric line from a subpixel which is adjacent to the subpixel area in a lengthwise direction of the common electric line. The method for manufacturing an organic light emitting display device further includes electrically connecting the auxiliary common electric line to a subpixel which is adjacent to the subpixel area in a lengthwise direction of the common electric line.

### BRIEF DESCRIPTION OF THE DRAWINGS

FIGS. 1 to 5 are perspective views illustrating a manufacturing method of an OLED device in accordance with an embodiment.

FIG. 6 is a cross-sectional view of the OLED device of FIG. 5 taken along a line VI-VI.

FIG. 7 is a cross-sectional view of the OLED device of FIG. 5 taken along a line VII-VII.

FIG. 8 is an OLED device in accordance with another embodiment.

### DETAILED DESCRIPTION OF CERTAIN INVENTIVE EMBODIMENTS

With reference to the accompanying drawings, embodiments will be described. As those skilled in the art would realize, the described embodiments may be modified in various ways, without departing from the spirit or scope of the present invention.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section.

The terminology used herein is for the purpose of describing particular embodiments only and is not intended to be limiting of the invention. As used herein, the singular forms “a” “an” and “the” are intended to include the plural forms as well, unless the context clearly and specifically indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region.

Although a driving circuit unit including two thin film transistors and a capacitor is described in embodiments below, other embodiments are not limited to the structure of the driving circuit unit in the described embodiments. A structure of the driving circuit unit can be varied in other forms in accordance with an application.

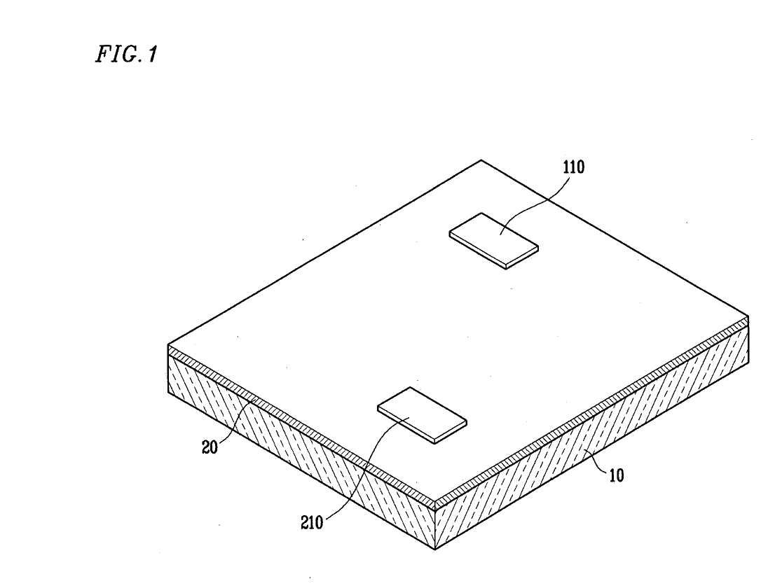

FIGS. 1 to 5 illustrate a method for manufacturing the OLED device according to an embodiment. A substrate 10 on which a driving circuit unit is formed in only one subpixel area is illustrated in FIGS. 1 to 5 for convenience. Each of the subpixel area can display, for example, a red, a green or a blue color. Three subpixels can constitute one pixel.

As illustrated in FIG. 1, a substrate 10 is provided in a driving circuit unit of the OLED device in accordance with an embodiment. A substrate 10 can, for example, be made of a transparent glass or an opaque resin. Alternatively, other materials may be used, such as a flexible thin metal plate.

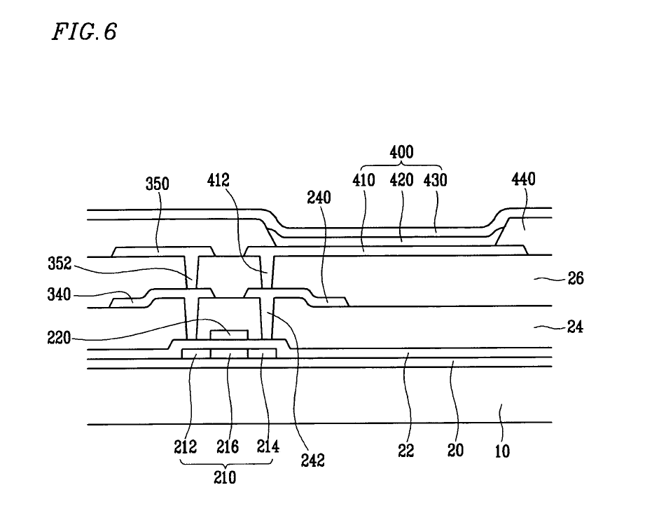

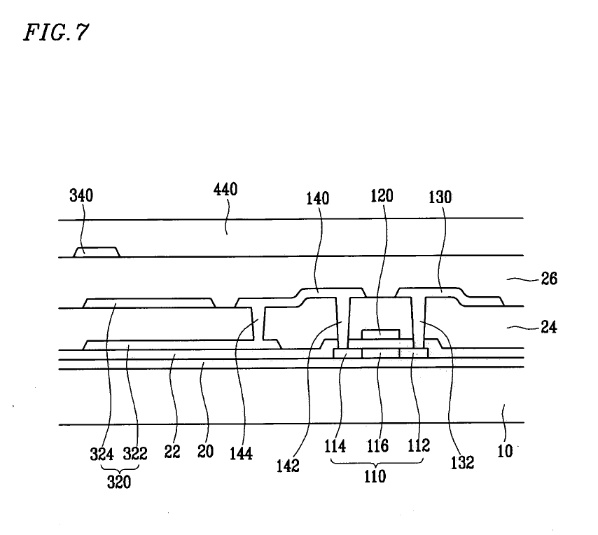

A buffer layer 20 is formed on the substrate 10. First and second semiconductor layers 110 and 210 are formed on the buffer layer 20 in a first thin film transistor (TFT) layer and a second TFT layer, respectively. At least two TFTs can be provided in each of the subpixels. The first and second semiconductor layers 110 and 210 each include source areas 112 and 212, drain areas 114 and 214, and channel areas 116 and 216, respectively. (shown in FIGS. 6 and 7) The first and second semiconductor layers 110 and 210 may include polysilicon.

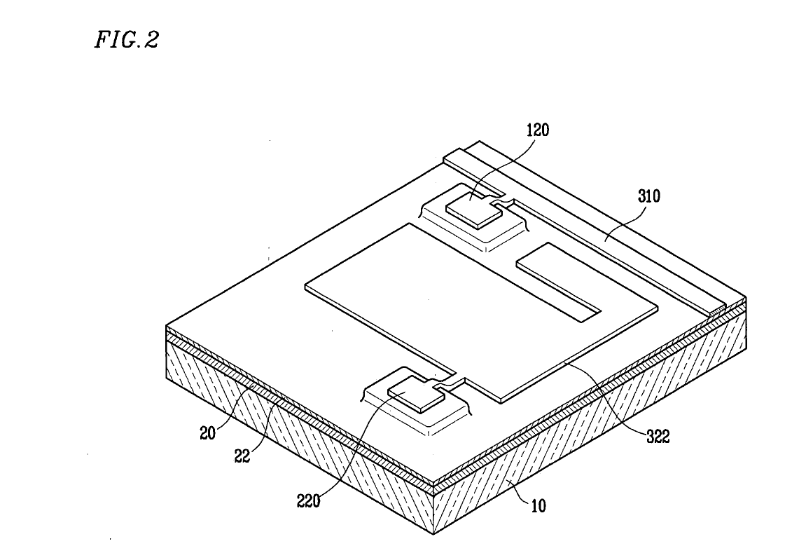

As illustrated in FIG. 2, a gate insulating layer 22 is formed on the buffer layer 20, and the first and second semiconductor layers 110 and 210. A first gate electrode 120, a scan line 310 integrally formed with the first gate electrode 120, a second gate electrode 220, and a lower capacitor electrode 322 integrally formed with the second gate electrode 220 are formed on the gate insulating layer 22.

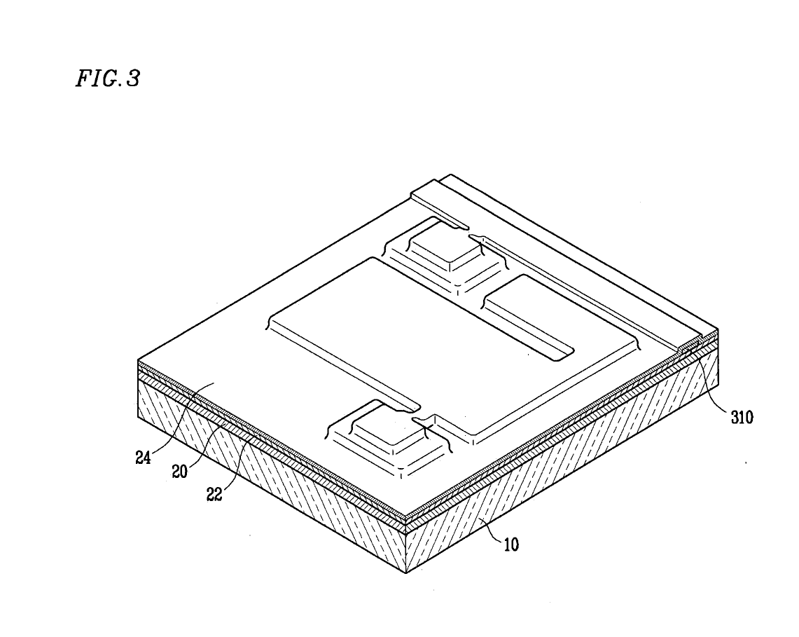

Then, as illustrated in FIG. 3, an interlayer dielectric (ILD) 24 is formed on the first gate electrode 120, the scan line 310, the second gate electrode 220, and the lower capacitor electrode 322.

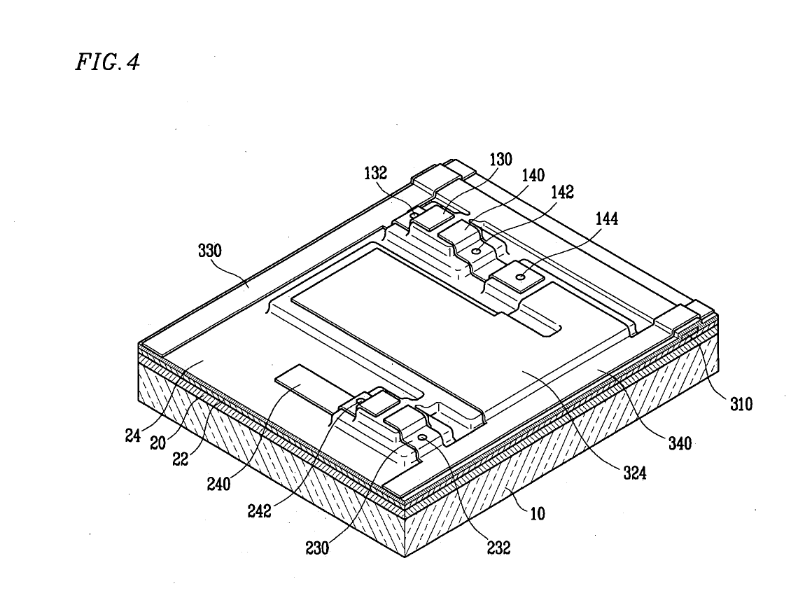

As illustrated in FIG. 4, a source electrode 130 and a drain electrode 140 of the first TFT, a data line 330 integrally formed with the source electrode 130, a source electrode 230 and a drain electrode 240 of the second TFT, an auxiliary common electric line 340 integrally formed with the source electrode 230, and an upper capacitor electrode 324 are formed on the interlayer dielectric 24. The upper capacitor electrode 324 is integrally formed with the auxiliary common electric line 340. The electrodes and lines may include a titanium (Ti) layer, an aluminum (Al) layer on the Ti layer, and a Ti layer on the Al layer.

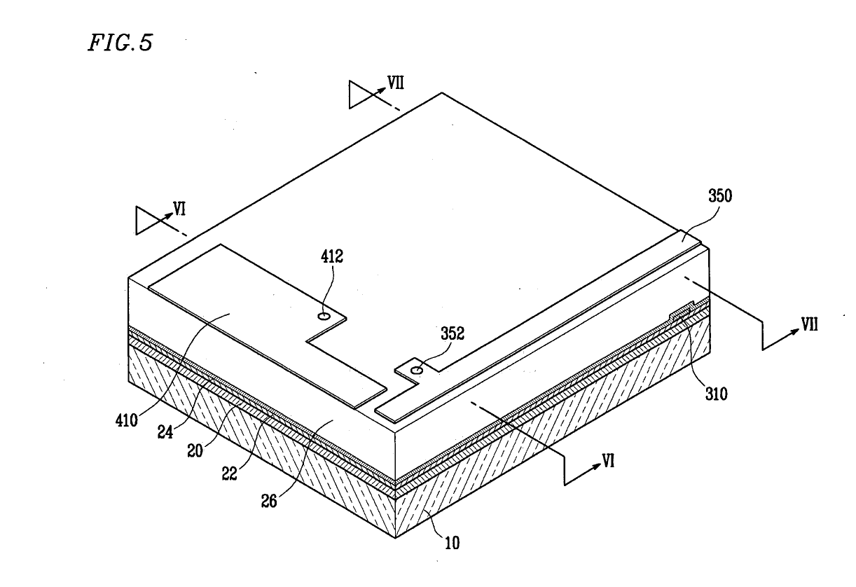

The auxiliary common electric line 340 is electrically connected to an adjacent auxiliary common electric line of another subpixel. The subpixel is arranged along a direction of which the common electric line 350 (shown in FIG. 5) is formed.

The data line 330 is formed along a direction to cross the scan line 310. For example, the data line 330 is formed along a direction to be perpendicular to the scan line 310. The source electrode 130 of the first TFT is electrically connected to the source area 112 through a via 132. (shown in FIG. 7) The drain electrode 140 is electrically connected to the drain area 114 through a via 142. (shown in FIG. 7) The drain electrode 140 is also electrically connected to the lower capacitor electrode 322 through another via 144. (shown in FIG. 7)

In addition, as shown in FIG. 4, the source electrode 230 of the second TFT is electrically connected to the source area 212 of the second TFT through a via 232. The drain electrode 240 is electrically connected to the drain area 214 through a via 242.

As illustrated in FIG. 5, a planarization layer 26 is formed on the substrate 10. A common electric line 350 and a first electrode 410 are formed on the planarization layer 26. Here, the first electrode 410 is an anode electrode for injecting holes. In some embodiments, the common electric line 350 and the first electrode 410 include silver (Ag). In some embodiments, they are multi-layered and include an indium tin oxide (ITO) layer, an Ag layer formed on the ITO layer, and a second ITO layer formed on the Ag layer.

The common electric line 350 is formed along a direction crosses the scan line 310 and is parallel to the data line 330. In addition, the common electric line 350 is electrically connected to the source electrode 230 of the second TFT through a via 352. Although not illustrated in FIG. 5, the common electric line 350 can be electrically connected to the upper capacitor electrode 324 formed therebelow through a via. In addition, the first electrode 410 is electrically connected to the drain electrode 240 of the second TFT through a via 412. (shown in FIG. 6)

In the embodiments of FIGS. 6 and 7 an emitting layer is formed on the OLED device of FIG. 5. FIG. 6 illustrates a cross section taken along a line VI-VI of FIG. 5 and FIG. 7 illustrates a cross section taken along a line VII-VII of FIG. 5, respectively.

As illustrated in FIGS. 6 and 7, a pixel defining layer 440 is formed on the first electrode 410. A portion of the first electrode 410 is exposed. An emitting layer 420 and a second electrode 430 are formed on the exposed portion of the first electrode 410. The emitting layer 420, the second electrode 430 and the first electrode 410 form a pixel unit 400. Here, the second electrode 430 is a cathode electrode for injecting electrons. The positions of the first and second electrodes can be exchanged in accordance with an application. The upper capacitor electrode 324 and the lower capacitor electrode 322 form a capacitor 320.

After the elements are formed on the substrate 10 in accordance with aforementioned description, these elements are sealed by, for example, using an incap glass or a metal cap or by forming a thin film.

In an embodiment, the common electric line 350 includes the same material as that included in the first electrode 410. For example, the material can include Ag. More specifically, the material may, for example, include an ITO layer, an Ag layer formed on the ITO layer, and an ITO layer formed on the Ag layer. A specific resistance of Ag is 1.62×10⁻⁶Ω·cm and that of aluminum (Al) is 2.2×10⁻⁶Ω·cm. That is, the specific resistance of Ag is less than that of Al. As a result, the common electric line 350 can reduce IR drop. Thus, It is possible to reduce unnecessarily consumed power and to prevent vertical crosstalk to enhance display power and quality performance.

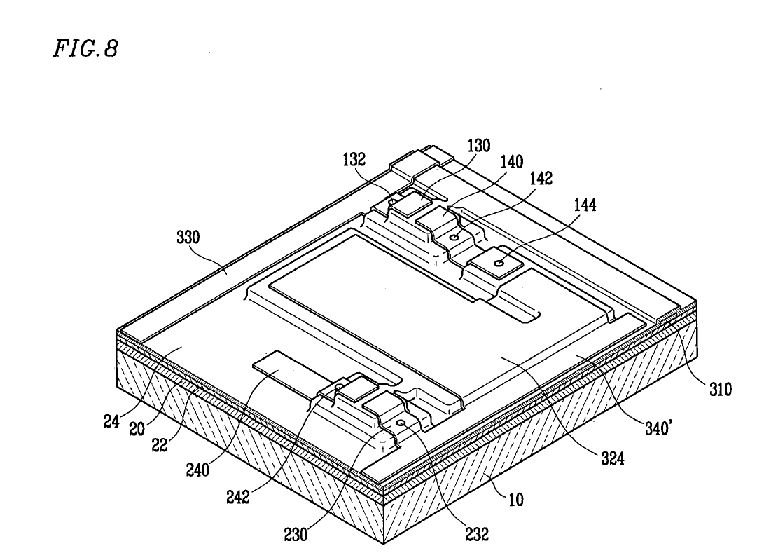

FIG. 8 illustrates a main portion of the OLED device in accordance with another embodiment. Another embodiment illustrated in FIG. 8 is similar to the aforementioned embodiment. Therefore, like elements are referred to as like reference numerals and detailed description thereof is omitted.

In another embodiment, auxiliary common electric line 340′ is electrically disconnected to an adjacent auxiliary common electric line of another subpixel. The subpixel is arranged along a direction of which the common electric line 350 is formed.

the above description has pointed out novel features of certain inventive aspects as applied to various embodiments, the skilled person will understand that various omissions, substitutions, and changes in the form and details of the device or process illustrated may be made without departing from the scope of the invention.

What is claimed is:

1. An organic light emitting display device, comprising:
a driving circuit unit comprising first and second thin film transistors arranged in a subpixel area on a substrate;
a light emitting unit formed on the driving circuit unit, comprising:
a first electrode electrically connected to a drain electrode of the second thin film transistor;
a second electrode arranged on the first electrode; and
a light emitting layer formed between the first and second electrodes; and
a common electric line electrically connected to a source electrode of the second thin film transistor,
wherein the common electric line and the first electrode are formed on the same layer and are formed of the same material.

2. The device of claim 1, wherein the first electrode is an anode electrode.

3. The device of claim 2, wherein the anode electrode comprises silver (Ag).

4. The device of claim 3, wherein the anode electrode comprises:
a first layer comprising indium tin oxide;
a second layer comprising silver formed on the first layer; and
a third layer comprising indium tin oxide formed on the second layer.

5. The device of claim 1, wherein the second thin film transistor comprises:
a second semiconductor layer, comprising:
a source area;
a drain area; and
a channel area;
a second gate electrode formed on the second semiconductor layer; and
source and drain electrodes formed on the second gate electrode,
wherein a gate insulating layer is formed between the second semiconductor layer and the second gate electrode, and an interlayer dielectric is formed between the second gate electrode and the source and drain electrodes.

6. The device of claim 5, wherein a first gate electrode of the first thin film transistor and a scan line electrically connected to the first gate electrode are formed on the gate insulating layer, and the source and drain electrodes of the first thin film transistor and a data line are formed on the interlayer dielectric, and wherein the data line is integrally formed with the source electrode of the first thin film transistor.

7. The device of claim 6, wherein a lower capacitor electrode is formed on the gate insulating layer, the lower capacitor electrode being integrally formed with the second gate electrode, and
wherein an upper capacitor electrode is formed on the interlayer dielectric.

8. The device of claim 7, wherein a planarization layer is formed on the upper capacitor electrode, the lower capacitor electrode is electrically connected to the drain electrode of the first thin film transistor, and the upper capacitor electrode is electrically connected to a common electric line formed on the planarization layer.

9. The device of claim 7, wherein a planarization layer is formed on the upper capacitor electrode, an auxiliary common electric line is formed on the interlayer dielectric, and at least one of the source electrode of the second thin film transistor and the upper capacitor electrode is electrically connected to a common electric line formed on the planarization layer, wherein the auxiliary common electric line is integrally formed with the upper capacitor electrode and the source electrode of the second thin film transistor.

10. The device of claim 9, wherein the auxiliary common electric line is electrically isolated from a subpixel which is adjacent to the subpixel area in a lengthwise direction of the common electric line.

11. The device of claim 9, wherein the auxiliary common electric line is electrically connected to a subpixel which is adjacent to the subpixel area in a lengthwise direction of the common electric line.

12. An organic light emitting display device, comprising:
a substrate;
a first semiconductor layer of first thin film transistor layer and a second semiconductor layer of a second thin film transistor layer in a subpixel area on the substrate, each semiconductor layer comprising:
a source area;
a drain area; and
a channel area;
a gate insulating layer formed on the first and second semiconductor layers;
a first gate electrode of the first thin film transistor, a second gate electrode of the second thin film transistor, and a scan line electrically connected to the first gate electrode formed on the gate insulating layer;
an interlayer dielectric formed on the first and second gate electrodes, the scan line and the gate insulating layer;
respective source and drain electrodes of the first and second thin film transistors and a data line formed on the interlayer dielectric, wherein the data line is formed with the source electrode of the first thin film transistor, and arranged to cross the scan line;
a planarization layer formed on the respective source and drain electrodes of the first and second thin film transistors, the data line, and the interlayer dielectric;
a light emitting unit formed on the planarization layer, comprising:
a first electrode electrically connected to the drain electrode of the second thin film transistor;
a light emitting layer formed on the first electrode; and
a second electrode formed on the light emitting layer; and
a common electric line electrically connected to the source electrode of the second thin film transistor,
wherein the common electric line and the first electrode of the light emitting unit are formed on the same layer and are formed of the same material.

13. The device of claim 12, further comprising:
a lower capacitor electrode, comprising the same material as the second gate electrode, and formed on the gate insulating layer; and
an upper capacitor electrode formed between the interlayer dielectric and the planarization layer, wherein the lower capacitor electrode is electrically connected to the drain electrode of the first thin film transistor, and the upper capacitor electrode is electrically connected to the common electric line.

14. The device of claim 13, further comprising an auxiliary common electric line, which is integrally formed on the interlayer dielectric with the upper capacitor electrode and the source electrode of the second thin film transistor.

15. The device of claim 14, wherein the auxiliary common electric line is electrically isolated from a subpixel which is adjacent to the subpixel area in a lengthwise direction of the common electric line.

16. The device of claim 14, wherein the auxiliary common electric line is electrically connected to a subpixel which is adjacent to the subpixel area in a lengthwise direction of the common electric.

17. The device of claim 12, wherein the first electrode of the light emitting unit is an anode electrode.

18. The device of claim 17, wherein the anode electrode comprises silver.

19. The device of claim 18, wherein the anode electrode comprises:
a first layer comprising indium tin oxide;
a second layer comprising silver formed on the first layer; and
a third layer comprising indium tin oxide formed on the second layer.

20. A method for manufacturing an organic light emitting display device, the method comprising:
providing a substrate;
forming a first semiconductor layer of a first thin film transistor and a second semiconductor layer of a second thin film transistor in a subpixel area on the substrate;
forming a gate insulating layer on the first and second semiconductor layers;
forming on the gate insulating layer, a first gate electrode of the first thin film transistor, a scan line connected to the first gate electrode, a second gate electrode of the second thin film transistor, and a lower capacitor electrode connected to the second gate electrode;
forming an interlayer dielectric on the first and second gate electrodes, the scan line and the lower capacitor electrode;
forming respective source and drain electrodes of the first and second thin film transistors, a data line integrally formed with the source electrode of the first thin film transistor, and an upper capacitor electrode;
forming a planarization layer on the interlayer dielectric;
forming a common electric line electrically connected to the source electrode of the second thin film transistor and the upper capacitor electrode, the common electric line comprising the same material as a first light emitting unit electrode electrically connected to the drain electrode of the second thin film transistor; and
sequentially stacking a light emitting layer and a second light emitting unit electrode on the first light emitting unit electrode.

21. The method of claim 20, further comprising forming an auxiliary common electric line integrally formed with the upper capacitor electrode and the source electrode of the second thin film transistor.

22. The device of claim 21, further comprising electrically isolating the auxiliary common electric line from a subpixel which is adjacent to the subpixel area in a lengthwise direction of the common electric line.

23. The device of claim 21, further comprising electrically connecting the auxiliary common electric line to a subpixel which is adjacent to the subpixel area in a lengthwise direction of the common electric line.
